(19) United States
(12) Patent Application Publication
(10) Pub. No.: US 2026/0248026 A1
(43) Pub. Date: Aug. 20, 2026

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Kai-Fung Chang, Taipei City (TW); Li-Hui Cheng, New Taipei City (TW); Ying-Ching Shih, Hsinchu City (TW)

(73) Assignee: Taiwan Semiconductor Manufacturing Company, Ltd., Hsinchu (TW)

(21) Appl. No.: 19/058,014

(22) Filed: Feb. 20, 2025

(51) Int. Cl. H01L 23/31; H01L 21/56; H01L 23/00; H01L 23/29; H01L 23/48; H01L 25/11

(52) U.S. Cl. CPC H10W 74/121; H10W 74/01; H10W 90/00; H10W 20/20; H10W 70/09; H10W 70/60; H10W 74/473; H10W 90/22

(57) ABSTRACT

A semiconductor package includes a first redistribution structure, a semiconductor die, an encapsulant, a second redistribution structure, and a fence structure. The semiconductor die disposes on the first redistribution structure. The encapsulant disposes on the first redistribution structure and laterally wraps the semiconductor die. The second redistribution structure disposes on the semiconductor die and the encapsulant, wherein the first and second redistribution structures are electrically connected. The fence structure is disposed on the first redistribution structure and between the semiconductor die and the encapsulant, and wraps around a first portion of the semiconductor die neighboring the first redistribution structure and covers sidewalls of the first portion, wherein the encapsulant and the fence structure are made of different materials.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 15 are schematic cross-sectional views illustrating steps of a manufacturing process for forming a package component in accordance with some embodiments.

FIG. 16A illustrates a cross-sectional view of an intermediate structure of a package component with die attach film protrusion in accordance with another embodiment.

FIGS. 16B to 16D are schematic top views illustrating the intermediate structure in accordance with another embodiment.

FIGS. 17 to 21 are schematic cross-sectional views illustrating steps of a manufacturing process for forming a package component in accordance with some embodiments.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In general, a semiconductor die attaches to a carrier through a die attach film. After the attachment, since the need for thinning the semiconductor die is required, a die thinning process is performed on the frontside of the semiconductor die. Therefore, the semiconductor dies receive a large compression and make the die attach film which is under the semiconductor die extend beyond the sidewall of the semiconductor die to form a protrusion. After encapsulated by an encapsulant and removing the die attach film, a recess will be formed in the encapsulant in the location and shape of the protrusion. However, when forming a redistribution structure on the encapsulant, the dielectric layer of the redistribution structure may form on the recess, causing the dielectric layer uneven and lead to deformation. Therefore, a method to avoid the formation of the recess is required.

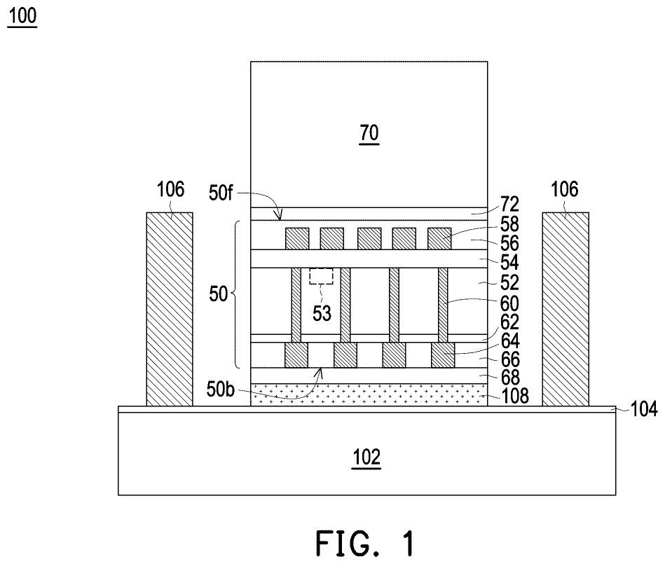

FIGS. 1 to 15 are schematic cross-sectional views illustrating steps of a manufacturing process for forming a first package component 100, in accordance with some embodiments.

FIG. 1 illustrates a cross-sectional view of a semiconductor die and through vias on a first carrier, in accordance with an embodiment. A first carrier 102 is provided, and a release layer 104 is formed on the first carrier 102. Through vias 106 are formed on the release layer 104. The semiconductor die 50 is bonded to the release layer 104 through a die attach film 108.

The first carrier 102 may be a glass carrier substrate, a ceramic carrier substrate, or the like. The first carrier 102 may be a wafer, such that multiple packages can be formed on the carrier substrate 102 simultaneously. The release layer 104 may be formed of a polymer-based material, which may be removed along with the first carrier 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The top surface of the release layer 104 may be leveled and may have a high degree of planarity.

As an example to form the through vias 106, the formation of the through vias 106 includes forming a patterned photoresist layer (not shown) with openings on a seed layer (not shown), where portions of the seed layer are exposed by the openings in the patterned photoresist layer. A conductive material is then deposited or plated within the openings of the patterned photoresist layer. Subsequently, the patterned photoresist layer and the excess seed layer are removed, leaving the remaining conductive structures as the through vias 106. In some embodiments, the material of the through vias 106 may include a metal material such as copper or copper alloys, or the like.

In some embodiments, the semiconductor die 50 includes a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In some embodiments the semiconductor die 50, for example, includes through substrate vias or functions as a local silicon interconnect die (LSI).

The semiconductor die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The semiconductor substrate 52 has a frontside surface (e.g., the surface facing upwards in FIG. 1) and a backside surface (e.g., the surface facing downwards in FIG. 1).

Devices 53 (as shown in the dotted line square in FIG. 1) may be formed at the frontside surface of the semiconductor substrate 52. The devices 53 may be active devices (e.g., transistors, diodes, etc.), capacitors, resistors, etc. The interconnect structure 54 electrically interconnects the devices to form an integrated circuit. The interconnect structure 54 may be formed by, for example, metallization patterns (not shown) in dielectric layers. The metallization patterns include metal lines and vias formed in one or more low-k dielectric layers.

The semiconductor die 50 further includes top connectors 58, such as conductive pillars (for example, formed of a metal such as copper). In some embodiments, the top connectors 58 are electrically connected with the interconnect structure 54 and are electrically coupled to the devices 53 through the metal lines in the interconnect structure 54. The top connectors 58 may be formed by, for example, plating, printing, deposition or the like.

A protective layer 56 laterally encapsulates the top connectors 58. Initially, the protective layer 56 may bury the top connectors 58, such that the topmost surface of the protective layer 56 is above the topmost surfaces of the top connectors 58. The protective layer 56 may be a polymer such as benzocyclobutene (BCB), polybenzoxazole (PBO), polyimide, or the like; a nitride such as silicon nitride; an oxide such as silicon oxide, phosphosilicate glass (PSG), borosilicate glass (BSG), boro-phosphate-silicate glass (BPSG), or a combination thereof. The protective layer 56 may be formed, for example, by spin coating, lamination, chemical vapor deposition (CVD), or the like.

The semiconductor die 50 further includes through substrate vias (TSVs) 60 that penetrate through the semiconductor substrate 52. In some embodiments, the TSVs may electrically connect to the top connectors 58 through the interconnect structure 54, and the devices 53 are electrically connected with the TSVs 60 through the interconnect structure 54 as well. In some embodiments, the TSVs 60 are through semiconductor vias (e.g. through silicon vias) for passing through the semiconductor substrate 52 (e.g. the semiconductor substrate 52 being a silicon-containing substrate). In some embodiments, the TSVs 60 include conductive metallic vias. The materials of the conductive metallic vias include copper, a copper alloy, aluminum, an aluminum alloy or a combination thereof. In some embodiments, each TSVs further includes a barrier layer (not shown) between the conductive via and the semiconductor substrate 52. The barrier layer includes Ta, TaN, Ti, TiN, CoW or a combination thereof.

Then, a passivation layer 62 may be formed over the backside surface of the semiconductor substrate 52 to laterally wrapping around partials of the bottom sidewalls of the TSVs 60. In some embodiments, the passivation layer 62 may be formed by a deposition process and a subsequent planarization process, for example.

The semiconductor die 50 further includes bottom connectors 64 and a protective layer 66 over the passivation layer 62 and the TSVs 60. In some embodiments, the bottom connectors 64 are connected to the TSVs 60, so that the top connectors 58 and the bottom connectors 64 and the devices 53 are electrically connected through the interconnect structure 54 and the TSVs 60. The materials and the formation method of the bottom connectors 64 are similar to those of the top connectors 58, and details are omitted herein. The protective layer 66 includes organic insulating materials (such as polyimide, epoxy resin, acrylic resin, phenol resin, benzocyclobutene (BCB), polybenzoxazole (PBO), or any other suitable poly-based dielectric material) or inorganic insulating materials. The protective layer 66 may be deposited using any suitable method, such as, ALD, CVD, PVD, or the like.

A dielectric layer 68 is formed on the backside surface 50b of the semiconductor die 50. In some embodiments, the dielectric layer 68 is formed on the bottom connectors 64 and a protective layer 66 to protect the exposed surface of bottom connectors 64 before bonding the semiconductor die 50 on the first carrier 102. The dielectric layer 68 may be a polymer such as PBO, polyimide, BCB; a nitride such as silicon nitride; an oxide such as silicon oxide, PSG, BSG, BPSG, or a combination thereof.

In some embodiments, the semiconductor die 50 is provided with a carrier substrate 70 attached to the frontside surface 50f of the semiconductor dies 50. In some embodiments, the carrier substrate 70 is attached to the protective layer 56 of the semiconductor dies 50 through an adhesive layer 72. During the processing, the carrier substrate 70, the adhesive layer 72, and the semiconductor die 50 may constitute a semiconductor structure. The carrier substrate 70 includes a semiconductor substrate such as a silicon substrate. In some embodiments, the carrier substrate 70 and the first carrier 102 may be formed of the same material. The adhesive layer 72 may be formed from any suitable adhesive material.

The die attach film (DAF) 108 is disposed on the backside of the semiconductor dies 50 and adheres the semiconductor dies 50 to the first carrier 102. The DAF 108 may be applied to the dielectric layer 68 which is formed on the backside surface 50b of the semiconductor dies 50. The DAF 108 may be formed by deposition, lamination, or any other suitable technique.

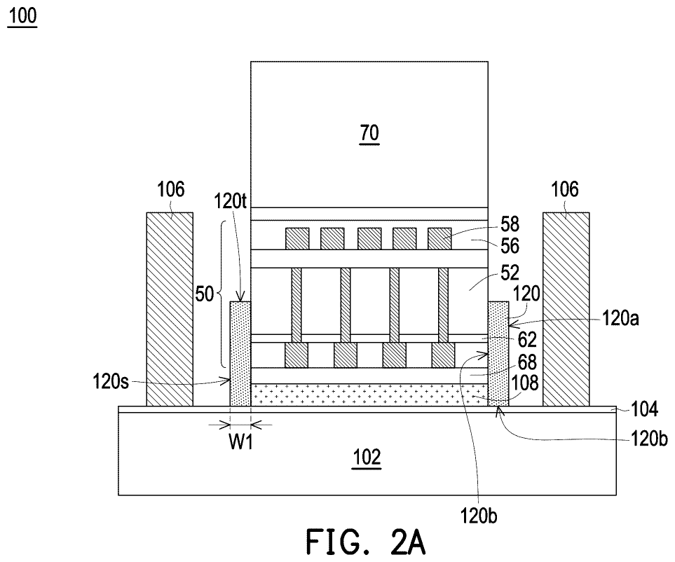

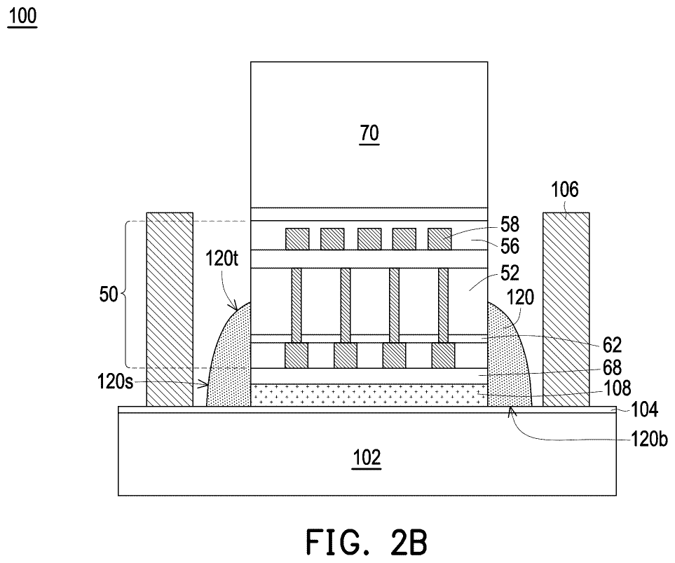

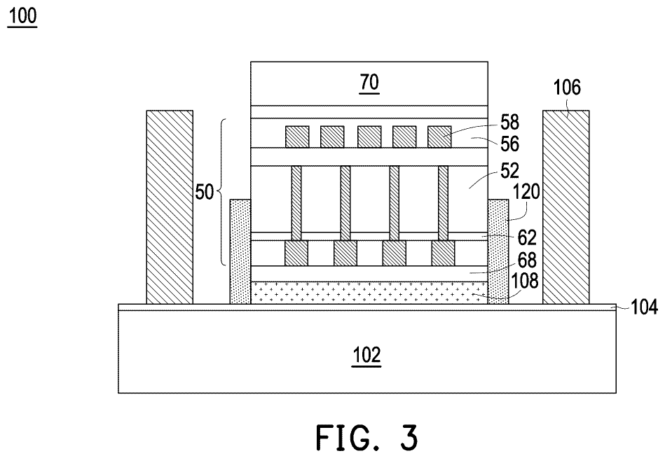

FIGS. 2A and 2B illustrate formation of a fence structure, in accordance with an embodiment. In FIG. 2A, a fence structure 120 that is formed of an insulating material wraps around a bottom portion of the semiconductor die 50 and covering sidewalls of the bottom portion. For instance, a material of the fence structure 120 may include epoxy resin, silica rubber, a combination thereof or the like. In some embodiments, the fence structure 120 may include plurality of fillers, such as silica, alumina, boron nitride (BN), and diamond. The fence structure 120 may be formed by a dispensing process followed by a curing process, an over-molding process, or may be formed by a suitable deposition method. The fence structure 120 may has multiple shape. In FIG. 2A, in this embodiment, the fence structure 120 has a width W1 (i.e. extending distance between its outer sidewall 120a and its inner sidewall 120b along a direction perpendicular to the sidewall of the semiconductor die 50). In some embodiments, the fence structure 120 has a substantially uniform width W1. In some embodiments, the width W1 of the fence structure 120 is almost uniform from top to bottom (i.e. either measuring at the top surface 120t, or measuring at the bottom surface 120b of the fence structure 120 or at any position in-between). That is, the sidewall 120s of the fence structure 120 is parallel to the sidewall of the semiconductor die 50. In some embodiments, the width W1 of the fence structure 120 is range from 0.1 μm to 9000 μm. In FIG. 2B, in some embodiment, the width W1 of the fence structure 120 is getting wider from the top surface 120t of the fence structure 120 to the bottom surface 120b of the fence structure 120. That is, the width W1 of the fence structure 120 is non-uniform. In a cross-section view of the fence structure 120, the sidewall 120s of the fence structure 120 has a curve profile. However, the disclosure is not limited thereto. In some alternative embodiment, the width W1 of the fence structure 120 may get wider from the bottom surface 120b of the fence structure 120 to the top surface 120t of the fence structure 120. In the following FIGS. 3 to 15, the fence structure 120 is shown with the same or similar configuration of the fence structure 120 of FIG. 2A, but the disclosure is not limited thereto, and the fence structure 120 may be formed with the configuration of the fence structure 120 shown in FIG. 2B.

The fence structure 120 covers the whole sidewall of the die attach film 108 and the dielectric layer 68. In some embodiments, the fence structure 120 does not cover the sidewall of the semiconductor substrate 52 and the passivation layer 62. The fence structure 120 covers a portion of the sidewall of the protective layer 66. The topmost surface of the fence structure 120 is higher than the topmost surface of the dielectric layer 68. Therefore, after the removal of the die attach film 108 and the planarization process in subsequent steps, the fence structure 120 may have remain portion in the encapsulant 122 to cover the bottom sidewall of the semiconductor die 50.

FIG. 3 illustrates a thinning process of the semiconductor die, in accordance with an embodiment. A thinning process may be performed to partially remove the carrier substrate 70 of the semiconductor die 50 for thinning the carrier substrate 70. After performing the thinning process, the thickness of the carrier substrate 70 is reduced. In some embodiments, the thinning process includes a mechanical grinding process, a CMP process, an etching process, or combinations thereof. Since the fence structure 120 is surrounding the sidewall of the die attach film 108, during the thinning process, the die attach film 108 may not extend beyond the sidewall of the integrated circuit die 50 to form a protrusion even if under the compression.

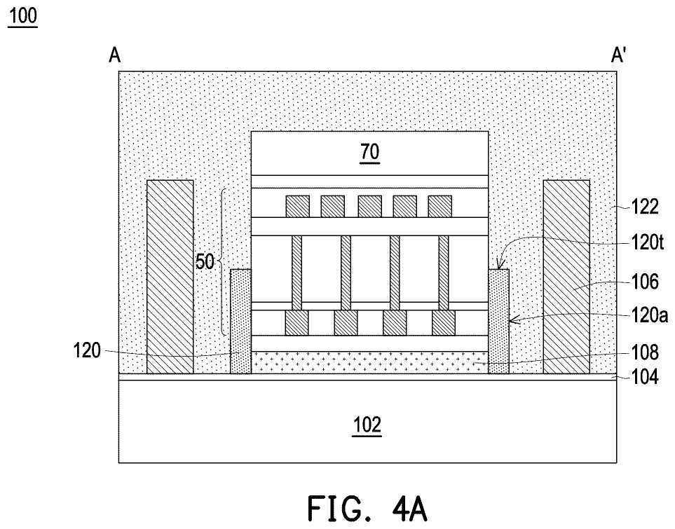

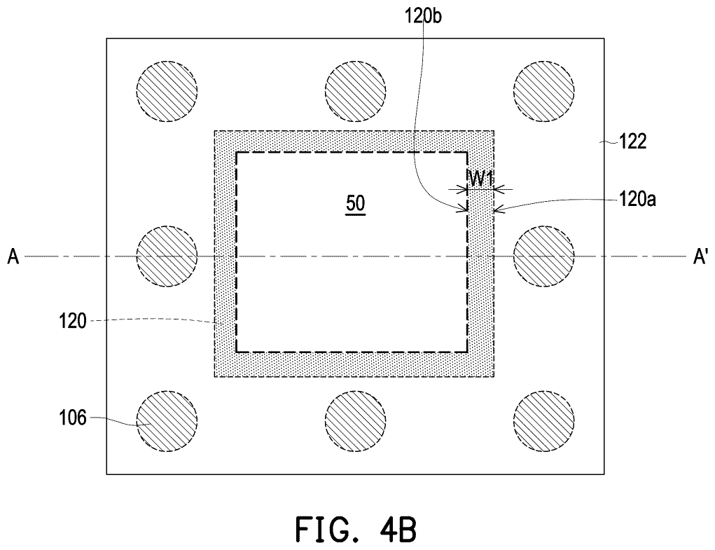

FIG. 4A illustrates formation of an encapsulant, in accordance with an embodiment. An encapsulant 122 is formed on the first carrier 102 and laterally wrapping around the semiconductor die 50, the through vias 106, and the fence structure 120. Thus, the fence structure 120 is located between the semiconductor die 50 and the encapsulant 122. That is, the encapsulant 122 covers the top surface 120t and the outer sidewall 120a of the fence structure 120. The top surface 120t and the outer sidewall 120a of the fence structure 120 constitute an interface between the fence structure 120 and the encapsulant 122. The encapsulant 122 may be applied by compression molding, transfer molding, or the like, and may be formed over the carrier substrate 70 such that the through vias 106 and/or the semiconductor die 50 are buried or covered. The encapsulant 122 may be applied in liquid or semi-liquid form and then subsequently cured. The encapsulant 122 may include a molding compound, epoxy, or the like. In some embodiments, the encapsulant 122 and the fence structure 120 are made of different materials, and the encapsulant 122 and the fence structure 120 include an insulating composite material including a base material (such as polymer) and a plurality of fillers in the base material. The filler sizes of the fillers in the fence structure 120 are different from the filler sizes of the fillers in the encapsulant 122. In some embodiments, the filler sizes of the fillers in the fence structure 120 are smaller than the filler sizes of the fillers in the encapsulant 122.

FIG. 4B illustrates a top view along a cross-section A-A′ of FIG. 4A. The fence structure 120 is surrounding the sidewall of the semiconductor die 50 and directly contact the sidewall of the semiconductor die 50 in the top view. In this embodiment, the fence structure 120 includes the width W1 between an outer sidewall 120a and an inner sidewall 120b, the width W1 is along a direction perpendicular with the sidewall of the semiconductor die 50. As shown in FIG. 4B, the width W1 of the fence structure 120 is uniform at four sides of the semiconductor die 50. In some embodiments, the width W1 of the fence structure 120 at each of the four sides may be different respectively. For example, the width W1 of the fence structure 120 at one side of the semiconductor die 50 is different from the width W1 of the fence structure 120 at another side of the semiconductor die 50. In some embodiments, the width W1 at one side may be non-uniform. For example, the width W1 at the middle portion is larger than the width W1 close to corner of the semiconductor die 50. In another embodiments, the outer sidewall 120a of the fence structure 120 may be of any shape and the width W1 may be in any range, as long as the fence structure 120 completely covers the sidewall of the semiconductor die 50.

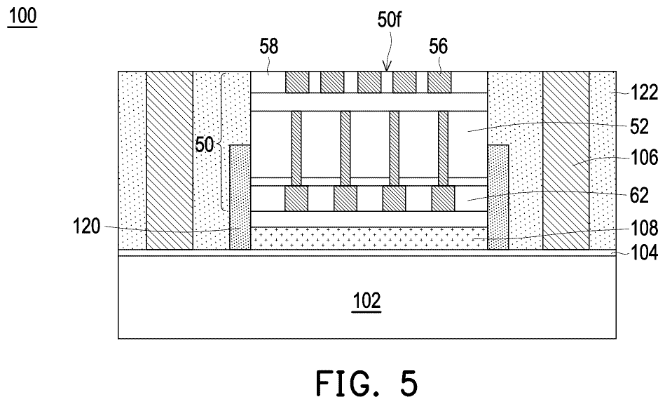

FIG. 5 illustrates a planarization of the encapsulant, in accordance with an embodiment. A planarization process is performed on the encapsulant 122 to expose the frontside surface 50f of the semiconductor die 50, the top surface of the through vias 106 and the top connectors 58. The planarization process may also remove material of the through vias 106, the protective layer 56, and/or the top connectors 58 until the top connectors 58 and through vias 106 are exposed. The top surfaces of the through vias 106, the top connectors 58, the protective layer 56, and the encapsulant 122 are substantially coplanar after the planarization process within process variations. The planarization process may be, for example, a chemical-mechanical polish (CMP), a grinding process, or the like. In some embodiments, the planarization may be omitted, for example, if the through vias 106 and/or the top connectors 58 are already exposed. After the planarization process, the top surface of the through vias 106, the semiconductor die 50, and the encapsulant 122 may be leveled and may have a high degree of planarity.

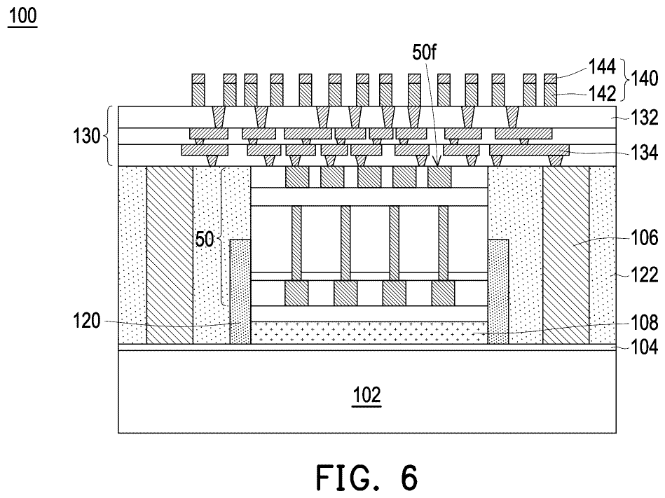

FIG. 6 illustrates formation of a first redistribution structure and first connector structures, in accordance with an embodiment. A first redistribution structure 130 is formed on the frontside surface 50f of the semiconductor die 50. That is, the first redistribution structure 130 is formed on the encapsulant 122, the through vias 106, and the semiconductor die 50. The first redistribution structure 130 includes dielectric layers 132 and metallization patterns 134. The metallization patterns may also be referred to as redistribution layers or redistribution lines. The first redistribution structure 130 is shown as an example having three layers of metallization patterns. More or fewer dielectric layers and metallization patterns may be formed in the first redistribution structure 130.

The dielectric layers 132 may be deposited over the semiconductor die 50, the encapsulant 122, and the through vias 106. The dielectric layer 132 is formed of a photo-sensitive material such as polybenzoxazole (PBO), polyimide (PI), benzocyclobutene (BCB), or the like. In some embodiments, the dielectric layer 132 and the fence structure 120 are made of different materials. The metallization patterns 134 may be formed within the dielectric layers 132, for example, by forming line cavities or via cavities at each level of the dielectric layers 132, by depositing at least one conductive material in the various cavities at each level, and by planarizing the at least one conductive material at each level. The metallization patterns 134 may include metal line structures, metal via structures, metal pad structures, and/or integrated metal line and via structures. The metallization patterns 134 may include the conductive material, and the conductive material may comprise a metal, like copper, titanium, tungsten, aluminum, or the like.

Then, the first connector structures 140 are formed on the first redistribution structure 130. The first connector structures 140 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the first connector structures 140 include metal pillars 142 with solder materials 144. The metal pillars 142 are formed for external connection of the first redistribution structure 130. The metal pillars 142 have bump portions on and extending along the major surface of the dielectric layer 132, and electrically couple to the metallization pattern 134. As a result, the metal pillars 142 are electrically coupled to the through vias 106 and the semiconductor die 50. The metal pillars 142 may be formed of the same material as the metallization pattern 134. In some embodiments, the metal pillars 142 have a different size than the metallization patterns 134. The metal pillars 142 may be solder free and have substantially vertical sidewalls. The solder materials 144 formed on the metal pillars 142 may include tin and a conductive material such as copper, aluminum, gold, nickel, silver, palladium, or a combination thereof. In some embodiments, the solder materials 144 are formed by initially forming a layer of solder through evaporation, electroplating, printing, solder transfer, ball placement, or the like. Once a layer of solder has been formed on the structure, a reflow may be performed in order to shape the material into the desired bump shapes.

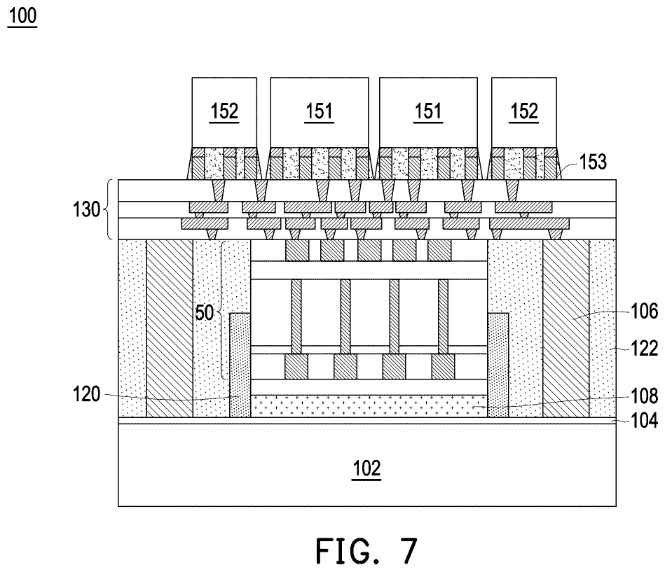

FIG. 7 illustrates bonding of semiconductor devices and formation of an underfill layer, in accordance with an embodiment. The first semiconductor devices 151 (two are shown) and the second semiconductor devices 152 (two are shown) are arranged side by side and are bonded to the first redistribution structure 130 through the first connector structures 140. The first semiconductor devices 151 may be the same type devices, the second semiconductor devices 152 may be the same type of devices, but the first and second semiconductor devices 151 and 152 are different types of devices. At least one semiconductor device 151 and one semiconductor device 152 are electrically connected to the semiconductor die 50. In some embodiments, the first semiconductor devices 151 and the second semiconductor device 152 may include dynamic random access memory (DRAM) dies, static random access memory (SRAM) dies, high bandwidth memory (HBM) dies, hybrid memory cube (HMC) dies, central processing unit (CPU) dies, graphics processing unit (GPU) dies, system-on-a-chip (SoC) unit dies, power management integrated circuit (PMIC) dies, radio frequency (RF) dies, sensor dies, micro-electro-mechanical-system (MEMS) dies, signal processing dies (such as digital signal processor, DSP) etc., the present disclosure is not limited thereto. In some embodiments, the semiconductor devices 151 and 152 may include the same type of dies, such as SoC dies, but they may perform different functions or of different sizes. The first semiconductor devices 151 and second semiconductor devices 152 may be formed in processes of a same technology node, or may be formed in processes of different technology nodes. The first semiconductor devices 151 and the second semiconductor devices 152 are shown as an example having two semiconductor devices respectively. More or fewer semiconductor devices may be formed on the first redistribution structure 130 via the first connector structures 140.

The underfills 153 are formed between the first redistribution structure 130 and the semiconductor devices 151 and 152, and the underfills 153 wrap around the first connector structures 140 below the semiconductor devices 151 and 152. For example, the underfill 153 wraps around sidewalls of the metal pillars 142 and the solder materials 144. The underfill 153 may be formed by injecting an underfill material around the first connector structures 140. Any known underfill material application method may be used, which may be, for example, the capillary underfill method, the molded underfill method, or the printed underfill method. In some embodiments, the material of the underfill 153 may be same as the material of the fence structure 120. In other embodiments, the material of the underfill 153 may be different from the material of the fence structure 120.

FIG. 8 illustrates formation of a molding compound, in accordance with an embodiment. The molding compound 160 is formed on the first redistribution structure 130 and laterally encapsulates the semiconductor devices 151 and 152 and the underfill 153. The molding compound 160 may be formed over the semiconductor devices 151 and 152 such that the semiconductor devices 151 and 152 are buried or covered. The molding compound 160, for example, is a molding compound made of a polymeric material (such as epoxy resins, phenolic resins, silicon-containing resins, or other suitable resins), a dielectric material having low permittivity (Dk) and low loss tangent (Df) properties, or other suitable materials. In some embodiments, the material of the molding compound 160 may be similar with the material of the encapsulant 122. In some embodiments, the molding compound 160 may also include inorganic fillers or compounds (e.g., silica, clay, etc.) as additives to optimize its coefficient of thermal expansion (CTE). Additionally, the material of the molding compound 160 may differ from that of the underfill 153.

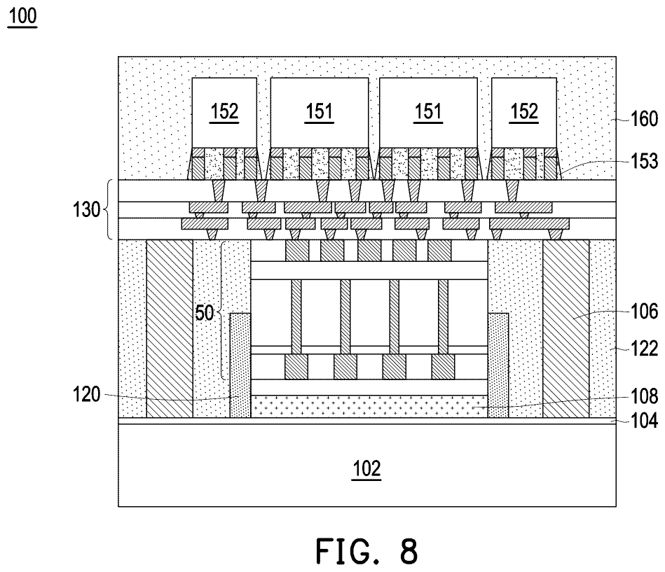

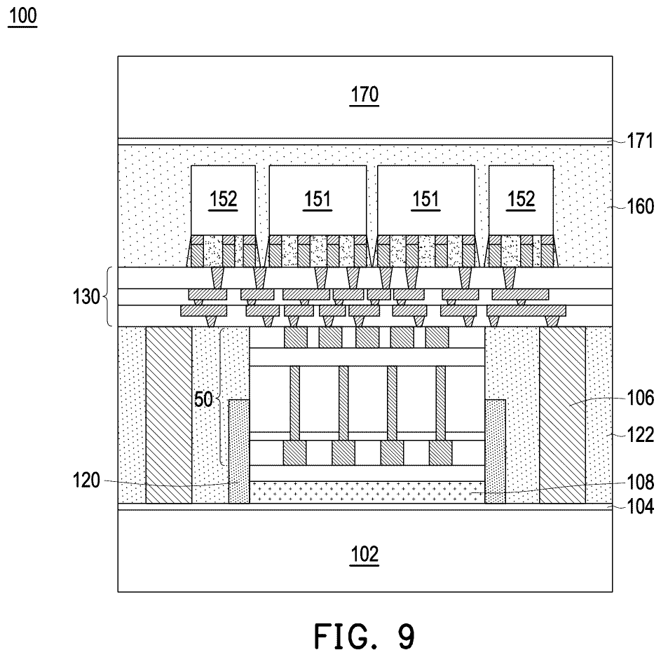

FIG. 9 illustrates bonding of a second carrier, in accordance with an embodiment. A second carrier 170 may be attached to the molding compound 160 through a suitable temporary adhesive layer 171. The second carrier 170 may be a glass carrier substrate, a ceramic carrier substrate, or the like. The temporary adhesive layer 171 may be formed of a polymer-based material, which may be removed along with the second carrier 170 from the overlying structures that will be formed in subsequent steps. In some embodiments, the temporary adhesive layer 171 is an epoxy-based thermal-release material, which loses its adhesive property when heated, such as a light-to-heat-conversion (LTHC) release coating. In other embodiments, the temporary adhesive layer 171 may be an ultra-violet (UV) glue, which loses its adhesive property when exposed to UV lights. The surface of the temporary adhesive layer 171 may be leveled and may have a high degree of planarity.

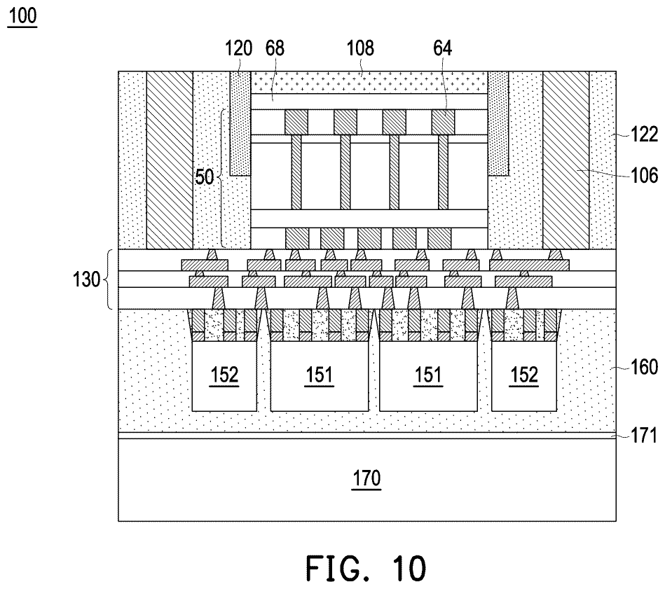

FIG. 10 illustrates removal of the first carrier, in accordance with an embodiment. Subsequently, the first package component 100 shown in FIG. 9 is flipped over and the first carrier 102 and the release layer 104 is then removed. For example, by performing a thermal anneal process at a temperature that deactivates the release layer 104. Upon debonding of the release layer 104, the first carrier 102 may be detached. After the removal of the first carrier 102, the die attach film 108 is exposed for the cleaning process in subsequent steps. Additionally, the bottom surfaces of the through vias 106, the encapsulant 122, and the fence structure 120 are exposed.

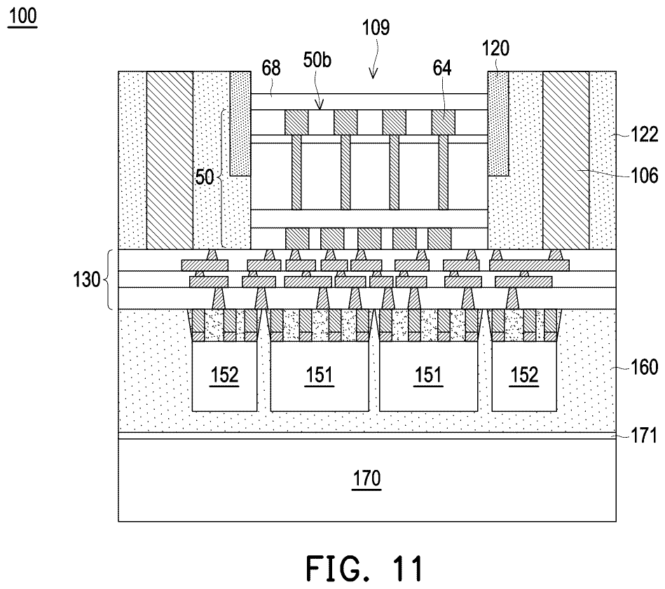

FIG. 11 illustrates removal of a die attach film, in accordance with an embodiment. The die attach film 108 is removed by an etching process or a cleaning process to form a cavity 109 surrounded by the fence structure 120. The cleaning process is performed until that any remaining portions of the die attach film 108 are fully removed. In an embodiment, the etching/cleaning process may be performed using a plasma cleaning process, a wet etching process, combinations of these, or the like. However, any suitable cleaning may be performed. Once the die attach film 108 has been fully removed, the dielectric layer 68 on the backside surface 50b of the semiconductor die 50 is exposed. In an embodiment, the die attach film 108 can be removed using either a dry etching process (e.g., a plasma etching process) or a wet etching process. In an embodiment in which a wet etching process is utilized, a solvent or etchant such as dimethyl sulfoxide (DMSO), TMAH, combinations of these, or the like, is applied to the die attach film 108. Once in physical contact, the solvent or etchant is utilized to either physically or chemically remove the material of the die attach film 108. However, any suitable process to remove the die attach film 108 may be utilized. After the removal of the die attach film 108, a portion of the bottom sidewall of the fence structure 120 is exposed.

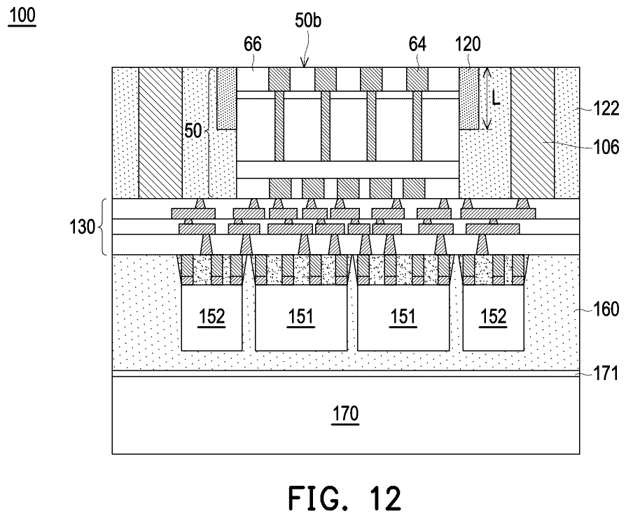

FIG. 12 illustrates a planarization of the encapsulant, in accordance with an embodiment. A planarization process is performed on the backside surface 50b of the semiconductor die 50. The planarization process may also remove the dielectric layer 68, portions of the encapsulant 122, the through vias 106, and the fence structure 120, until the bottom connectors 64 are exposed. The planarized surfaces (e.g., the top surfaces facing upwards in FIG. 12) of the through vias 106, the bottom connectors 64, the fence structure 120, and the encapsulant 122 are substantially flush with each other and are coplanar after the planarization process within process variations. The planarization process may be, for example, a chemical-mechanical polish (CMP), a grinding process, or the like. In some embodiments, after the planarization process, the remain portion of the fence structure 120 includes a length L from the bottom surface to the top surface of the fence structure 120, which is range from 0.1 μm to 600 μm.

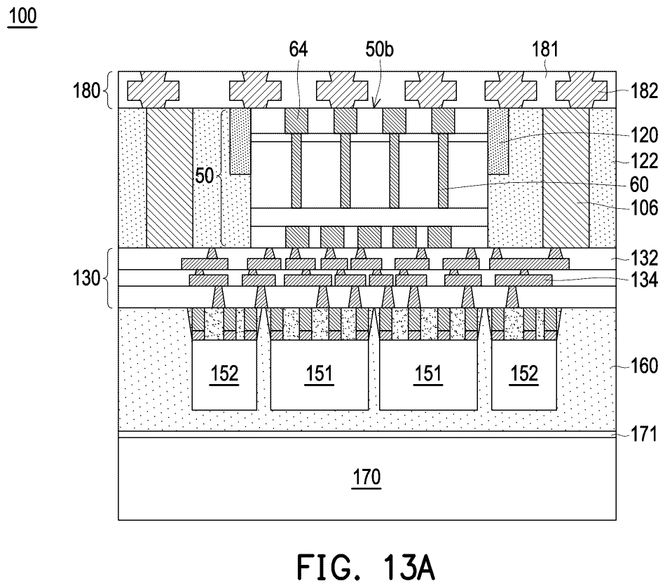

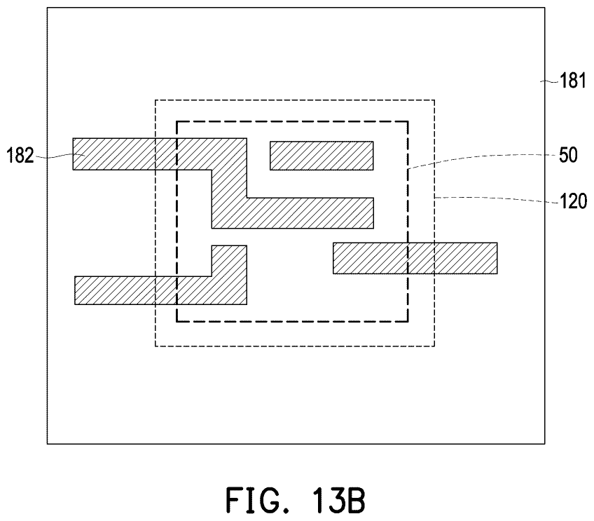

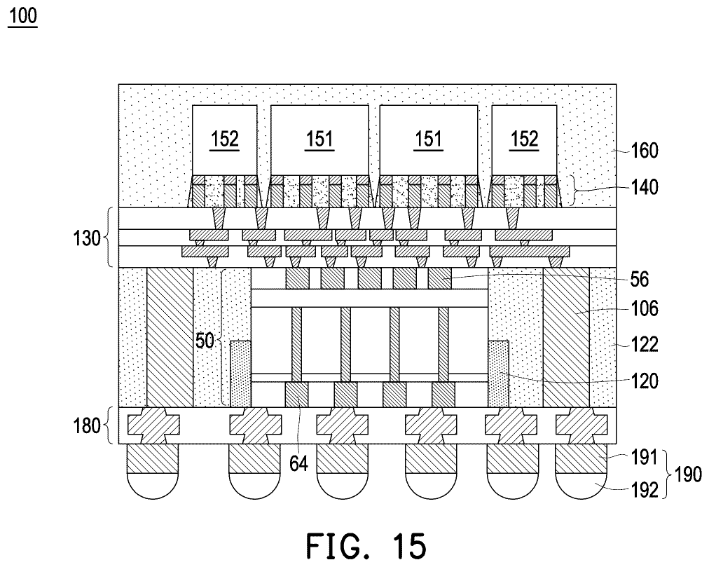

FIG. 13A illustrates formation of a second redistribution structure, in accordance with an embodiment. A second redistribution structure 180 may be formed on the backside surface 50b of the semiconductor die 50, over the encapsulant 122, and the through vias 106. In some embodiments, the fence structure 120 wraps around a portion of the semiconductor die 50 neighboring the second redistribution structure 180 and covering sidewalls of such portion (such portion being the upper portion in FIG. 13A but being the lower or bottom portion in FIG. 15). The fence structure 120 surrounds a periphery of a contact surface 50b between the semiconductor die 50 and the second redistribution structure 180. The contact surface 50b of the semiconductor die 50 and contact surfaces of the fence structure 120 and the encapsulant 122 (in contact with the second redistribution structure 180) are levelled and flush with each other. The second redistribution structure 180 includes dielectric layers 181 and metallization patterns 182. The metallization patterns may also be referred to as redistribution layers or redistribution lines. The metallization patterns 182 of the second redistribution structure 180 electrically connects to the bottom connectors 64 of the semiconductor die 50. The metallization patterns 182 of the second redistribution structure 180 may electrically connect to the metallization patterns 134 of the first redistribution structure 130 through the through vias 106. In some embodiments, the first redistribution structure 130 and the second redistribution structure 180 are electrically connected through the TSVs 60 of the semiconductor die.

The formation process of the second redistribution structure 180 is similar with the formation process of the first redistribution structure 130. The dielectric layers 181 may be deposited over the semiconductor die 50, the encapsulant 122, the fence structure 120, and the through vias 106. The dielectric layer 181 is formed of a photo-sensitive material such as polybenzoxazole (PBO), polyimide (PI), benzocyclobutene (BCB), or the like. The metallization patterns 182 may be formed within the dielectric layers 181, for example, by forming line cavities or via cavities at each level of the dielectric layers 181, by depositing at least one conductive material in the various cavities at each level, and by planarizing the at least one conductive material at each level. The metallization patterns 182 may include metal line structures, metal via structures, metal pad structures, and/or integrated metal line and via structures. The metallization patterns 182 may include the conductive material, and the conductive material may comprise a metal, like copper, titanium, tungsten, aluminum, or the like.

FIG. 13B illustrates top view of FIG. 13A, in accordance with an embodiment. The metallization patterns 182 electrically connect to the semiconductor dies 50 and extend to outside of the edge of the semiconductor dies 50 to electrically connect with other electrical components (not shown). Due to the presence of the fence structure 120, the die attach film 108 may not extend beyond the sidewall of the semiconductor die, therefore the recess which after the removal of the die attach film 108 may not be formed. Then, when forming the dielectric layers 181 of the second redistribution structure 180, the dielectric layers 181 have a high degree of planarity and without forming a hole or a groove due to the presence of the recess in the dielectric layers 181.

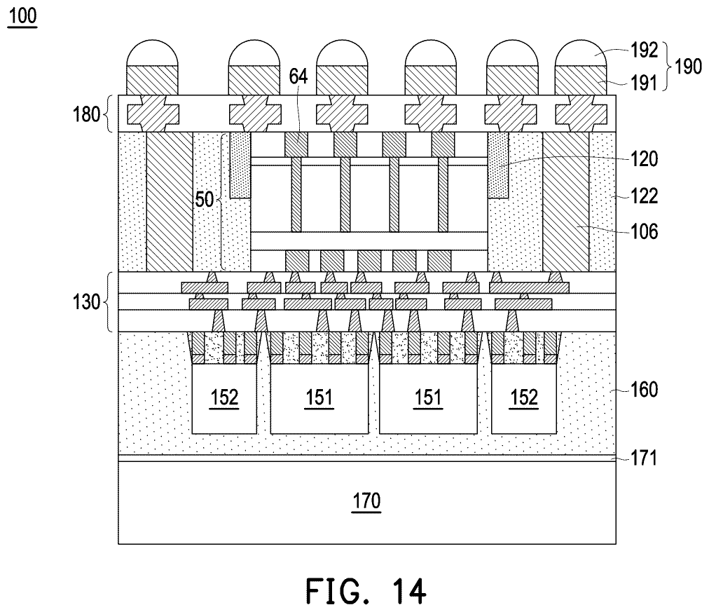

FIG. 14 illustrates formation of second connector structures, in accordance with an embodiment. The second connector structures 190 are formed on the second redistribution structure 180 and are electrically connected to the second redistribution structure 180. The second connector structures 190 include under bump metallizations (UBMs) 191 and external connectors 192 formed on the UBMs 191. The external connectors 192 may be placed on the UBMs 191 using a ball placement process and a reflow process. In some embodiments, the external connectors 192 may be or include controlled collapse chip connection (C4) bumps, ball grid array (BGA) balls, or the like. The external connectors 192 may be used to bond to an additional electrical component, which may be a semiconductor substrate, a package substrate, a printed circuit board (PCB), or the like.

FIG. 15 illustrates removal of a second carrier, in accordance with an embodiment. The first package component 100 is flipped over, then the second carrier 170 and the temporary adhesive layer 171 are removed. For example, by performing a thermal anneal process at a temperature that deactivates the temporary adhesive layer 171. Upon debonding of the temporary adhesive layer 171, the second carrier 170 may be detached. In some embodiments, the first package component 100 may connected to a circuit substrate (not shown) through second connector structures 190.

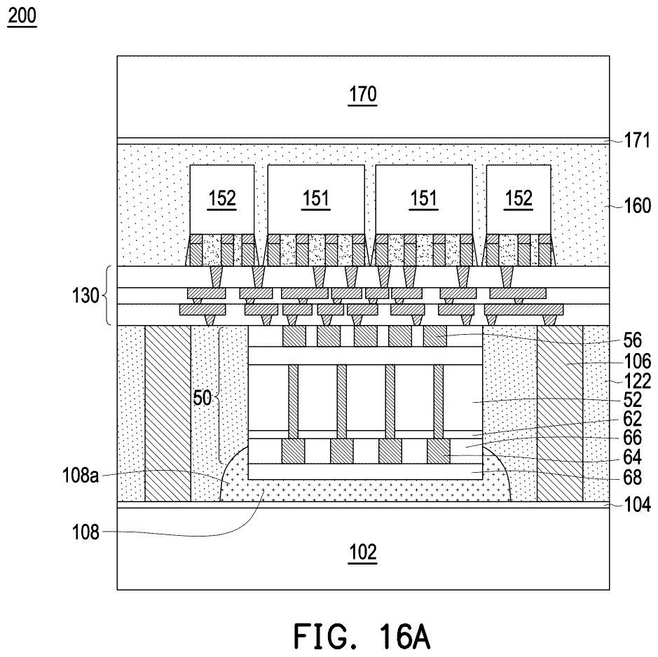

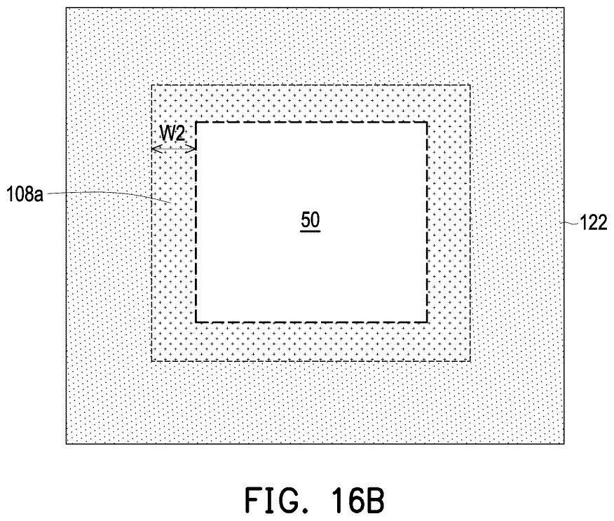

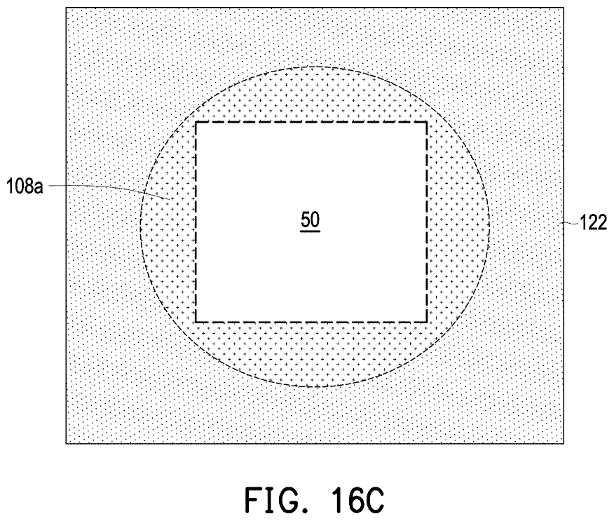

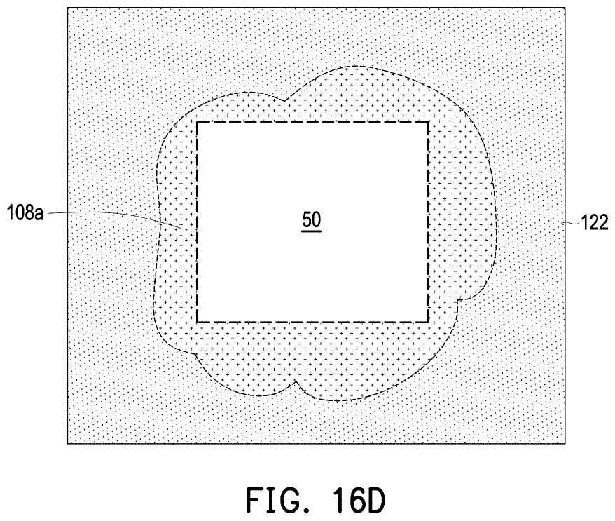

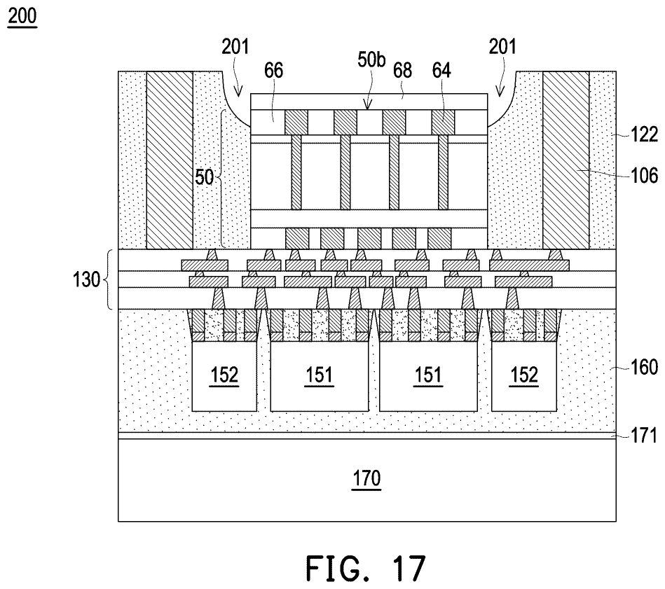

FIG. 16A illustrates a cross-sectional view of an intermediate structure of a package component with die attach film protrusion in accordance with another embodiment. FIG. 16B to 16D are schematic top views illustrating the intermediate structure in accordance with another embodiment. FIGS. 17 to 21 are schematic cross-sectional views illustrating steps of a manufacturing process for forming a package component in accordance with some embodiments

Referring to FIG. 16, the intermediate structure of the first package component 200 in FIG. 16A is similar to the intermediate structure of the first package component 100 shown in FIG. 9 except for that the fence structure 120 is not formed before the formation of the encapsulant 122. Refer to FIG. 16A, free of the fence structure, the through vias 106 and the semiconductor die 50 are encapsulated by the encapsulant 122 with the die attach film 108 wrapping around the bottom portion of the semiconductor die 50 and covering sidewalls of the bottom portion of the semiconductor die 50. Herein, during performing the thinning process (see FIG. 3), the die attach film 108 located between the semiconductor die 50 and the carrier 102 may be pressurized and compressed to become protruded out of the sidewalls of the semiconductor die 50 (i.e. extend beyond the span of the semiconductor die 50) to form a protrusion 108a. The protrusion 108a of the die attach film 108 covers the bottom portion of the semiconductor die 50. In an embodiment, the protrusion 108a of the die attach film 108 covers the whole sidewall of the dielectric layer 68 and a portion of the sidewall of the protective layer 66. In some embodiments, the protrusion 108a of the die attach film 108 may also covers a portion of the sidewalls of the semiconductor substrate 52 and the passivation layer 62. The encapsulant 122 is formed (which is shown in FIGS. 4A and 4B) after the thinning process and after the formation of the protrusion 108a, so that the encapsulant 122 fully covers the protrusion 108a of the die attach film 108 and the protrusion 108a encapsulated in the encapsulant 122 is located between the semiconductor die 50 and the encapsulant 122. As seen in FIG. 16A, the protrusion 108a has curved sidewalls in contact with the encapsulant 122.

FIG. 16B to 16D are schematic top views illustrating the intermediate structure in accordance with another embodiment. From the schematic top views, the protrusion 108a surrounding the semiconductor die 50 is in a ring-shape having a uniform width W2 (along any direction perpendicular to the periphery (in dot line) of the semiconductor die 50) as seen in FIG. 16B, or the protrusion 108a may be formed as a round or oval ring surrounding the square semiconductor die 50 with varying widths (measuring from the sidewall of the semiconductor die 50 to the outer sidewall of the protrusion 108a) as shown in FIG. 16C. In some embodiments, the protrusion 108a may be formed as an irregular ring surrounding the square semiconductor die 50 with varying widths (measuring from the sidewall of the semiconductor die 50 to the outer sidewall of the protrusion 108a) as shown in FIG. 16D. These shapes are, of course, merely examples and are not intended to limit the present disclosure.

FIG. 17 illustrates removal of a die attach film, in accordance with another embodiment. The second package component 200 is flipped over and the first carrier 102 is removed along with the release layer 104. For example, by performing a thermal anneal process at a temperature that deactivates the release layer 104. Upon debonding of the release layer 104, the first carrier 102 may be detached and then removed. Then, the die attach film 108 is removed by an etching process or a cleaning process. The etching/cleaning process in FIG. 17 is similar with the cleaning process shown in FIG. 11. The cleaning process is performed in order to ensure that any remaining portions of the die attach film 108 are fully removed. In an embodiment, the etching/cleaning process may be performed using a plasma cleaning process, a wet etching process, combinations of these, or the like. However, any suitable cleaning may be performed. Once the die attach film 108 has been fully removed, the dielectric layer 68 on the backside surface 50b of the semiconductor die 50 is exposed. In an embodiment, the die attach film 108 can be removed using either a dry etching process (e.g., a plasma etching process) or a wet etching process. In an embodiment in which a wet etching process is utilized, a solvent or etchant such as dimethyl sulfoxide (DMSO), TMAH, combinations of these, or the like, is applied to the die attach film 108. Once in physical contact, the solvent or etchant is utilized to either physically or chemically remove the material of the die attach film 108. However, any suitable process to remove the die attach film 108 may be utilized.

Through the removal of the die attach film 108, the protrusion 108a of the die attach film 108 is removed, a recess cavity or a recess is formed between the encapsulant 122 and the bottom portion of the semiconductor die 50 and the sidewalls of the bottom portion of the semiconductor die 50 are exposed form the recess 201. As such, the recess 201 is formed with profiles corresponding to the size and the shape of the die attach film 108 and the profiles of the protrusion 108a of the die attach film 108. That is, the recess 201 has the shape and size substantially the same as the protrusion 108a of the die attach film 108. The recess 201 exposes the sidewall of the dielectric layer 68 and a portion sidewall of the protective layer 66 of the semiconductor die 50. In other words, the backside surface 50b of the semiconductor die 50 is higher than the bottommost surface of the recess 201 at level height.

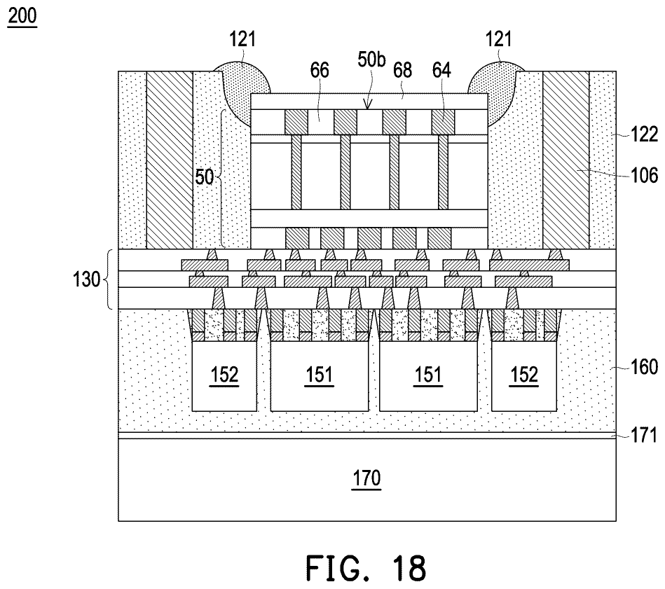

FIG. 18 illustrates formation of a fence structure material, in accordance with another embodiment. A fence structure material 121 is filled in the recess 201 to partially fill the recess 201, at least covering the sidewalls of the dielectric layer 68 and portions of sidewalls of the protective layer 66 (at least covering the peripheral portion and corners of the semiconductor die 50). Alternatively, the fence structure material 121 is formed to fill or partially fill the recess 201, taking the place of the die attach film 108 or at least the protrusion 108a of the die attach film 108, so that the fence structure material 121 conforms to the shape and size as the protrusion 108a of the die attach film 108. In some embodiments, the fence structure material 121 also formed over a portion of the dielectric layer 68 and the encapsulant 122. In some embodiments, the fence structure material 121 may be deposited to cover the whole top surface of the encapsulant 122, the through vias 106, and the dielectric layer 68. Formation of the fence structure material 121 may involve a deposition process, such as a chemical vapor deposition (CVD) process. A material of the fence structure material 121 may include epoxy resin, silica rubber, a combination thereof or the like. In some embodiments, the fence structure material 121 may include plurality of fillers, such as silica, alumina, boron nitride (BN), and diamond. In some embodiments, the encapsulant 122 and the fence structure material 121 are made of different materials, and the encapsulant 122 and the fence structure material 121 include an insulating composite material including a base material (such as polymer) and a plurality of fillers in the base material. The filler sizes of the fillers in the fence structure material 121 are different from the filler sizes of the fillers in the encapsulant 122. In some embodiments, the filler sizes of the fillers in the fence structure material 121 are smaller than the filler sizes of the fillers in the encapsulant 122.

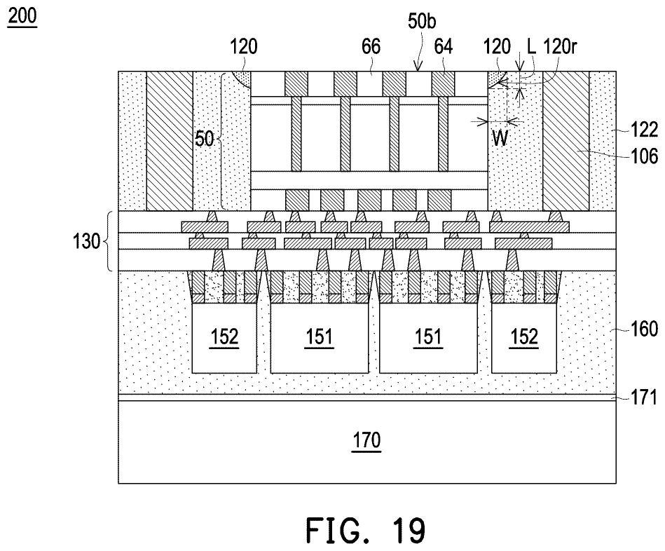

FIG. 19 illustrates a planarization of the encapsulant, in accordance with another embodiment. A planarization process is performed on the backside surface 50b of the semiconductor die 50. The planarization process may also remove material of the dielectric layer 68, portion of the encapsulant 122, the through vias 106, the fence structure material 121, and the bottom connectors 64 until the bottom connectors 64 are exposed. After the planarization process, the remain portion of the fence structure material 121 form a fence structure 120. Thus, the fence structure 120 is between the semiconductor die 50 and the encapsulant 122. An interface 120r between the fence structure 120 and the encapsulant 122 has a curve profile. The surfaces of the backside surface 50b of the semiconductor die 50, through vias 106, the fence structure 120, and the encapsulant 122 are substantially coplanar after the planarization process within process variations. The planarization process may be, for example, a chemical-mechanical polish (CMP), a grinding process, or the like. In some embodiments, after the planarization process, the fence structure 120 includes a length L from the bottom surface to the top surface of the fence structure 120, which is range from 0.1 μm to 600 μm. In some embodiments, the fence structure 120 includes a width W from the outer sidewall to the inner sidewall of the fence structure 120, which is range from 0.1 μm to 9000 μm.

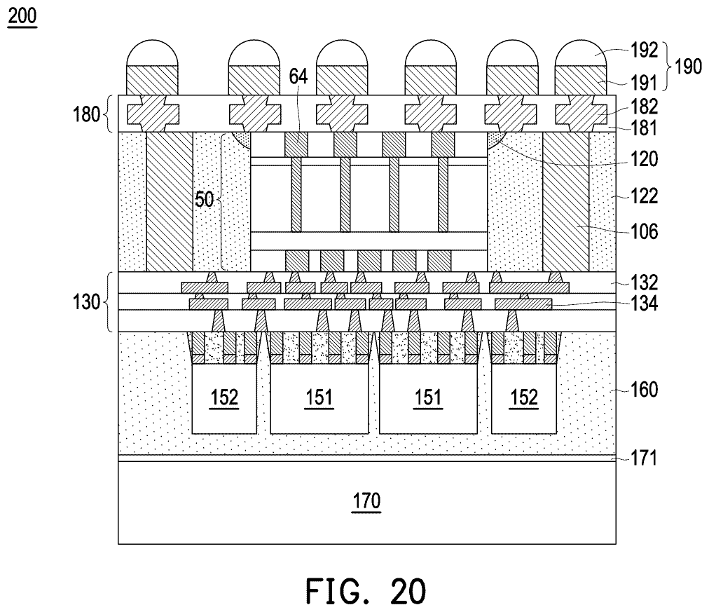

FIG. 20 illustrates formation of a second redistribution structure, under bump metallizations, and conductive connectors, in accordance with another embodiment. A second redistribution structure 180 may be formed on the backside surface 50b of the semiconductor die 50, the encapsulant 122, and the through vias 106. In some embodiments, the fence structure 120 wraps around a bottom portion of the semiconductor die 50 neighboring the second redistribution structure 180 and covering sidewalls of the bottom portion. The fence structure 120 surrounds a periphery of a contact surface between the semiconductor die 50 and the second redistribution structure 180. The contact surface of the semiconductor die 50 and bottom surfaces of the fence structure 120 and the encapsulant 122 are coplanar. The second redistribution structure 180 includes dielectric layers 181 and metallization patterns 182. The metallization patterns may also be referred to as redistribution layers or redistribution lines. The metallization patterns 182 of the second redistribution structure 180 electrically connects to the bottom connectors 64 of the semiconductor die 50. The metallization patterns 182 of the second redistribution structure 180 may electrically connect to the metallization patterns 134 of the first redistribution structure 130 through the through vias 106. In some embodiments, the first redistribution structure 130 and the second redistribution structure 180 are electrically connected through the TSVs 60 of the semiconductor die.

The formation process of the second redistribution structure 180 is similar with the formation process of the first redistribution structure 130. The dielectric layers 181 may be deposited over the semiconductor die 50, the encapsulant 122, the fence structure 120, and the through vias 106. The dielectric layer 181 is formed of a photo-sensitive material such as polybenzoxazole (PBO), polyimide (PI), benzocyclobutene (BCB), or the like. The metallization patterns 182 may be formed within the dielectric layers 181, for example, by forming line cavities or via cavities at each level of the dielectric layers 181, by depositing at least one conductive material in the various cavities at each level, and by planarizing the at least one conductive material at each level. The metallization patterns 182 may include metal line structures, metal via structures, metal pad structures, and/or integrated metal line and via structures. The metallization patterns 182 may include the conductive material, and the conductive material may comprise a metal, like copper, titanium, tungsten, aluminum, or the like.

Then, second connector structures 190 are formed on the second redistribution structure 180 and are electrically connected to the second redistribution structure 180. The second connector structures 190 include under bump metallizations (UBMs) 191 and external connectors 192 formed on the UBMs 191. The external connectors 192 may be placed on the UBMs 191 using a ball placement process and a reflow process. In some embodiments, the external connectors 192 are controlled collapse chip connection (C4) bumps, ball grid array (BGA) balls, or the like. The external connectors 192 may be used to bond to an additional electrical component, which may be a semiconductor substrate, a package substrate, a printed circuit board (PCB), or the like.

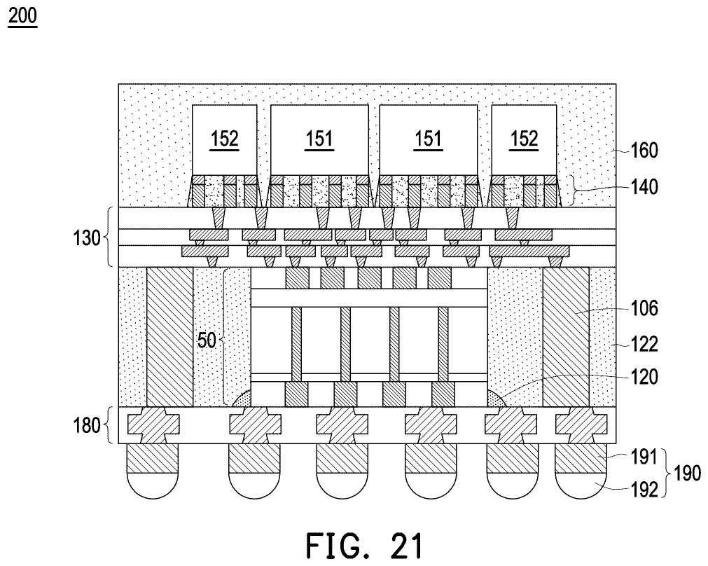

FIG. 21 illustrates removal of a second carrier, in accordance with another embodiment. The second package component 200 is flipped over, then the second carrier 170 and the temporary adhesive layer 171 are removed. For example, by performing a thermal anneal process at a temperature that deactivates the temporary adhesive layer 171. Upon debonding of the temporary adhesive layer 171, the second carrier 170 may be detached. In some embodiments, the second package component 200 may be connected to a circuit substrate (not shown) through second connector structures 190.

By the formation of the fence structure in the package component, the surface of the semiconductor die and the encapsulant have a high degree of planarity before forming the redistribution structure. As such, the formation of the dielectric layer of the redistribution structure would not be uneven and causing deformation of the redistribution structure.

In accordance with some embodiments of the present disclosure, a semiconductor package includes a first redistribution structure, a semiconductor die, an encapsulant, a second redistribution structure, and a fence structure. The semiconductor die disposes on the first redistribution structure. The encapsulant disposes on the first redistribution structure and laterally wraps the semiconductor die. The second redistribution structure disposes on the semiconductor die and the encapsulant, wherein the first and second redistribution structures are electrically connected. The fence structure is disposed on the first redistribution structure and between the semiconductor die and the encapsulant, and wraps around a first portion of the semiconductor die neighboring the first redistribution structure and covers sidewalls of the first portion, wherein the encapsulant and the fence structure are made of different materials.

In accordance with some embodiments of the present disclosure, a method of manufacturing a semiconductor package includes the following steps. Providing a first carrier. Attaching a semiconductor die to the first carrier through a die attach film. Forming a fence structure wrapping around a first portion of the semiconductor die and covering sidewalls of the first portion. Forming an encapsulant laterally wrapping the semiconductor die and the fence structure, wherein the fence structure and the encapsulant are formed of different materials. Removing the first carrier and removing the die attach film to form a cavity surrounding the semiconductor die.

In accordance with some embodiments of the present disclosure, a method of manufacturing a semiconductor package includes the following steps. Providing a first carrier. Attaching a semiconductor structure to the first carrier through a die attach film, wherein the semiconductor structure includes a semiconductor die attached to the die attach film located between the semiconductor die and the first carrier. Performing a thinning process to the semiconductor structure. Forming an encapsulant laterally wrapping the semiconductor die and the die attach film. Removing the first carrier and removing the die attach film to form a cavity exposing the semiconductor die; forming a fence structure surrounding the semiconductor die. Performing a first planarization process to remove a portion of the fence structure, a portion of the encapsulant, and a portion of the semiconductor die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first redistribution structure;
a semiconductor die, disposed on the first redistribution structure and including through semiconductor vias (TSVs);
an encapsulant, disposed on the first redistribution structure and laterally wrapping the semiconductor die;
a second redistribution structure disposed on the semiconductor die and the encapsulant, wherein the first and second redistribution structures are electrically connected through the TSVs of the semiconductor die; and
a fence structure, disposed on the first redistribution structure and between the semiconductor die and the encapsulant, wrapping around a first portion of the semiconductor die neighboring the first redistribution structure and covering sidewalls of the first portion,
wherein the encapsulant and the fence structure are made of different materials.

2. The semiconductor package of claim 1, wherein the second redistribution structure includes a dielectric layer and metallization patterns formed within the dielectric layer, and the dielectric layer and the fence structure are made of different materials.

3. The semiconductor package of claim 1, further comprising:
through vias extending through the encapsulant and electrically connecting the first redistribution structure and the second redistribution structure,
wherein contact surfaces of the through vias, the fence structure, and the encapsulant with the first redistribution structure are coplanar with one another.

4. The semiconductor package of claim 1, further comprising:
a first semiconductor device and a second semiconductor device disposed on the second redistribution structure, wherein the first semiconductor device and the second semiconductor device are arranged side by side and are bonded to the second redistribution structure through connector structures; and
a molding compound encapsulating the first semiconductor device and the second semiconductor device.

5. The semiconductor package of claim 1, wherein the fence structure is made of a first insulating material containing first fillers, and the encapsulant is made of a second insulating material containing second fillers.

6. The semiconductor package of claim 5, wherein filler sizes of the first fillers in the fence structure are different from filler sizes of the second fillers in the encapsulant.

7. The semiconductor package of claim 6, wherein the first fillers are smaller than the second fillers.

8. The semiconductor package of claim 1, wherein an interface between the fence structure and the encapsulant has a curve profile.

9. A method of manufacturing a semiconductor package, the method comprising:
providing a first carrier;
attaching a semiconductor die to the first carrier through a die attach film;
forming a fence structure wrapping around a first portion of the semiconductor die and covering sidewalls of the first portion;
forming an encapsulant laterally wrapping the semiconductor die and the fence structure, wherein the fence structure and the encapsulant are formed of different materials; and
removing the first carrier and removing the die attach film to form a cavity surrounding the semiconductor die.

10. The method of claim 9, wherein forming the fence structure is performed before forming the encapsulant and removing the first carrier and removing the die attach film, and the fence structure is formed to fully cover sidewalls of the die attach film and the sidewalls of the first portion.

11. The method of claim 10, further comprising:
forming a first redistribution structure on the semiconductor die and the encapsulant at a first side of the semiconductor die away from the die attach film and the first carrier, after forming the encapsulant, wherein the first redistribution structure and the semiconductor die are electrically connected.

12. The method of claim 11, further comprising:
disposing and bonding a first die and a second die on the first redistribution structure through connector structures there-between, wherein the first die and the second die are electrically connected with the semiconductor die through the first redistribution structure; and
forming a molding compound encapsulating the first die and the second die.

13. The method of claim 12, further comprising performing a planarization process after removing the die attach film and removing the first carrier to remove a portion of the fence structure exposed by the cavity, a portion of the encapsulant and a portion of the semiconductor die.

14. The method of claim 13, further comprising:
forming a plurality of through vias penetrating through the encapsulant; and
forming a second redistribution structure on a second side of the semiconductor die and on the encapsulant opposite to the first side, wherein the second redistribution structure are electrically connected with the first redistribution structure through the plurality of through vias.

15. The method of claim 9, wherein forming the fence structure is performed after forming the encapsulant and after removing the first carrier and removing the die attach film, and the fence structure is formed inside the cavity to cover the sidewalls of the first portion, and a planarization process is further performed after forming the fence structure to remove a portion of the fence structure inside the cavity, a portion of the encapsulant and a portion of the semiconductor die.

16. A method of manufacturing a semiconductor package, the method comprising:
providing a first carrier;
attaching a semiconductor structure to the first carrier through a die attach film, wherein the semiconductor structure includes a semiconductor die attached to the die attach film located between the semiconductor die and the first carrier;
performing a thinning process to the semiconductor structure;
forming an encapsulant laterally wrapping the semiconductor die and the die attach film;
removing the first carrier and removing the die attach film to form a cavity exposing the semiconductor die;
forming a fence structure surrounding the semiconductor die; and
performing a first planarization process to remove a portion of the fence structure, a portion of the encapsulant, and a portion of the semiconductor die.

17. The method of claim 16, wherein the fence structure is formed after forming the encapsulant and after removing the first carrier and removing the die attach film, and the fence structure is formed inside the cavity and surrounding the semiconductor die, and after performing the first planarization process, a first redistribution structure is performed on the planarized encapsulant and the semiconductor die.

18. The method of claim 17, wherein the thinning process is performed before forming the encapsulant to remove a portion of the semiconductor structure without damaging the semiconductor die, and the die attach film is protruded beyond a span of the semiconductor die during the thinning process.

19. The method of claim 16, wherein the fence structure is formed before forming the encapsulant, and the fence structure is not removed during removing the die attach film, and after performing the first planarization process, a first redistribution structure is performed on the planarized encapsulant and the semiconductor die.

20. The method of claim 16, further comprising:
forming through vias on the first carrier before forming the encapsulant, wherein the first planarization process removes portions of the through vias, so that surfaces of the through vias are coplanar with surfaces of the planarized semiconductor die.
